(19) United States
(12) Patent Application Publication
(10) Pub. No.: US 2008/0268382 A1
(43) Pub. Date: Oct. 30, 2008

(54) Glass Paste, Method for Producing Display by Using Same, and Display

(75) Inventors: Akihiko Tanaka, Kyoto-Shi (JP); Hidenobu Takada, Kyoto-Shi (JP); Minoru Tanemoto, Otsu-Shi (JP)

Correspondence Address: DARBY & DARBY P.C., P.O. BOX 770, Church Street Station, New York, NY, 10008-0770, US

(73) Assignee: TORAY INDUSTRIES, INC., Tokyo (JP)

(21) Appl. No.: 12/095,479

(22) PCT Filed: Nov. 28, 2006
(86) PCT No.: PCT/JP2006/323641

§ 371 Date: Jun. 16, 2008

(30) Foreign Application Priority Data
Nov. 30, 2005 (JP) 2005-345359

(51) Int. Cl. G03F 7/20; C03C 14/00

(52) U.S. Cl. 430/324; 501/32

(57) ABSTRACT

Disclosed is a glass paste containing a glass powder and an organic component, wherein a black pigment is composed of a complex oxide having a spinel structure and containing Co element and one or more metal elements other than Co element. Consequently, the glass paste is suppressed in color degradation at high temperatures, and thus enables to form a pattern having excellent color and degree of blackness after sintering.

### TECHNICAL FIELD

The present invention relates to a glass paste, a process for producing a display using the same, and a display.

### BACKGROUND ART

Plasma display panels (PDPs) are increasingly used in such fields as OA apparatuses and publicity displays, since they allow faster display and can be easily presented as larger devices than liquid crystal panels. Further, PDPs are highly expected used in such fields as high-grade television sets.

As the application fields of PDPs are expanding, high-resolution color PDPs, each with numerous display cells, attract attention. In a PDP, a slight gap formed between two glass substrates, namely, a front panel and a rear panel, is used as discharge spaces, in each of which plasma discharge is generated between an anode and a cathode, to generate ultraviolet radiation from the gas hermetically contained in the discharge space and to apply the ultraviolet radiation to the phosphor provided in the discharge space for light emission, hence for displaying. In this case, these electrodes are arranged in stripes in parallel to each other on the front panel and the rear panel, and the electrodes of the front panel and the electrodes of the rear panel are formed to oppose each other with a slight gap formed between them, and to be perpendicular to each other. Among PDPs, a plane discharge type PDP with a three-electrode structure suitable for color display using phosphors has multiple display electrode pairs parallel and adjacent to each other, and multiple address electrodes perpendicular to the respective display pairs. Meanwhile, the rear panel has barrier ribs formed in the spaces between the electrodes for preventing the crosstalk of light and securing the discharge spaces.

Among the abovementioned electrodes, the electrodes of the front panel require a technique of blackening for improving the contrast of the display screen, and methods in which a blackened silver paste is printed to a glass substrate by a printing method and fired at high temperature, to form a black electrode pattern are proposed (for example, see Patent Documents 1 and 2). As the black pastes used in these documents, pastes obtained by mixing not less than an equivalent amount of a metal oxide of iron, chromium, nickel, ruthenium or the like with silver are disclosed. However, the black pigments used for blackening have such problems that the pigments per se decline in blackness because of the oxidation-reduction reaction during firing, and that the reactions with the substrate, electrodes and dielectric can cause coloration to lower the color purity of the display. The discoloration problem such as the blackness decline caused by the heat of firing and coloration as described above is a cause for lowering the display performance of the display. Further, there is a problem that in the case where a black layer is formed between an ITO pattern and a silver electrode pattern, a general black pigment is too high in resistivity to allow conduction between the ITO and the silver electrodes. Further, a black paste that is used as the black layer formed between the ITO and the silver electrodes may also be used as a black stripe layer covering non-light-emitting portions as the case may be. In the case where both the layers are formed using the same material, if the resistance value of the material is too low, there are such problems that the reactive power becomes large and that the discharge cannot be stabilized, because of the relation with the panel capacity.

To solve these problems, a photosensitive conductive paste obtained by letting conductive fine metal particles contain 0.5 to 5 wt % of at least one metal selected from the group consisting of Ru, Cr, Fe, Co, Mn and Cu or any of their oxides is proposed (for example, see Patent Document 3). However, the black paste of Patent Document 3 has a problem that the inhibition of discoloration at high temperature is not sufficient.

### [Patent Document 1] JP61-176035A

### [Patent Document 2] JP4-272634A

### [Patent Document 3] JP10-333322A

### DISCLOSURE OF THE INVENTION

### Problem to be Solved by the Invention

This invention provides a glass paste capable of inhibiting the discoloration at high temperature and a display obtained by using said glass paste.

### Means for Solving the Problem

This invention relates to a glass paste containing a black pigment, glass powder and organic ingredient, wherein the black pigment is a black pigment composed of a composite oxide containing Co element and one or more metal elements other than the Co element and having a spinel structure.

It is preferred that the black pigment is a black pigment composed of at least one or more composite oxides selected from the group consisting of a Co—Mn based composite oxide, Co—Cu—Fe based composite oxide, Co—Mn—Fe based composite oxide, Co—Cu—Mn based composite oxide, Co—Ni—Mn based composite oxide, Co—Ni—Fe—Mn based composite oxide and Co—Ni—Cu—Mn based composite oxide.

It is preferred that the black pigment is a Co—Cu based composite oxide.

It is preferred that the Co—Cu based composite oxide is a black pigment composed of a composite oxide containing 30 to 70 wt % of Co and 5 to 30 wt % of Cu.

It is preferred that the average particle size of the black pigment is 0.01 to 0.5 μm.

It is preferred that the black pigment is a black pigment composed of a composite oxide containing 5 to 50 wt % of Co.

It is preferred that the black pigment is a black pigment composed of a composite oxide containing 5 to 50 wt % of Co and 5 to 50 wt % of Cu.

It is preferred that the black pigment is a black pigment composed of a composite oxide containing 5 to 50 wt % of Co, 5 to 50 wt % of Cu and 5 to 50 wt % of Mn.

It is preferred that the black pigment is a black pigment composed of a composite oxide containing 5 to 50 wt % of Co, 5 to 50 wt % of Ni and 5 to 50 wt % of Mn.

It is preferred that the specific surface area of the black pigment is 10 to 200 m²/g.

It is preferred that the average particle size Dg of the glass powder and the average particle size Db of the black pigment satisfy the following relation:

0.01<Db/Dg<0.9

It is preferred that the black pigment is contained by 5 to 40 wt % based on the weight of the inorganic powder.

It is preferred that the glass powder has a glass transition point of 400 to 490° C. and a softening point under load of 450 to 540° C.

It is preferred that a photosensitive organic ingredient is contained as the organic ingredient.

Further, this invention relates to a process for producing a display comprising the step of coating and drying said glass paste, for forming a paste coating film, the step of exposing the paste coating film through a photo mask, the step of developing the exposed paste coating film, and the step of forming a pattern by firing.

Furthermore, this invention relates to a display obtained by said production process.

### EFFECTS OF THE INVENTION

The glass paste of this invention, which contains a specific black pigment, can inhibit the discoloration at high temperature. Further, the display obtained by using said glass paste is higher in display contrast, lower in reactive power and more stable electrically.

### THE BEST MODES FOR CARRYING OUT THE INVENTION

This invention relates to a glass paste containing a black pigment, glass powder and organic ingredient, in which the black pigment is a black pigment composed of a composite oxide containing Co element and one or more metal elements other than the Co element and having a spinel structure.

The glass paste of this invention allows the prevention of discoloration at high temperature, since the black pigment used is a black pigment composed of a composite oxide containing Co element and one or more metal elements other than the Co element and having a spinel structure. Tricobalt tetroxide (Co₃O₄) as an oxide containing Co element but not containing any other metal element than the Co element and having a spinel structure causes slight discoloration at high temperature and is electrically stable, but since the pigment per se has a color of slightly brownish black, it is preferred to use a composite oxide containing Co element and one or more metal elements other than the Co element for obtaining a preferred hue. Further, depending on the characteristics of the actually used display panel, it is also an effective method to use CO₃O₄ together with a composite oxide containing Co element and one or more metal elements other than the Co element.

Other metal elements than Co element to be contained in the composite oxide constituting the black pigment include Cr, Fe, Mn, Cu, Ni, etc. Chromium includes divalent ions, trivalent ions and hexavalent ions, and it is known that a compound containing hexavalent ions is harmful. Chromium oxides are different in toxicity, depending on their valence numbers, but it is preferred not to contain chromium. Particular examples of the composite oxide include composite oxides containing two or more elements such as Co—Mn based composite oxide, Co—Cu—Fe based composite oxide, Co—Mn—Fe based composite oxide, Co—Cu—Mn based composite oxide, Co—Ni—Mn based composite oxide, Co—Ni—Fe—Mn based composite oxide, and Co—Ni—Cu—Mn based composite oxide. Among them, a Co—Mn based composite oxide, Co—Cu—Mn based composite oxide, Co—Ni—Mn based composite oxide and Co—Cu based composite oxide are preferred, since the discoloration at higher temperature can be prevented.

The black layer formed by using the glass paste of this invention can be used a black layer positioned between an ITO pattern layer and a silver electrode pattern layer or as a black matrix or black stripe layer. In the case where the black layer is formed for conduction between an ITO pattern and silver electrodes, it must allow the conduction between the ITO pattern and the silver electrode pattern. Further, in the case where it is used as a black matrix or black stripe layer, the panel capacity of the display must be taken into account. To satisfy both the properties, it is necessary to control the electric resistance of the black layer. Also in view of electric resistance control, it is preferred to use a composite oxide containing two or more elements such as a Co—Mn based composite oxide, Co—Cu—Fe based composite oxide, Co—Mn—Fe based composite oxide, Co—Cu—Mn based composite oxide, Co—Ni—Mn based composite oxide, Co—Ni—Fe—Mn based composite oxide or Co—Ni—Cu—Mn based composite oxide. Further, in the case where the electric resistance is too low since any of the abovementioned composite oxides only is used, a black pigment with a relatively high electric resistance can be used together in addition to the composite oxide with a relatively low electric resistance, to appropriately control the electric resistance. As the black pigment with a high electric resistance, CO₃O₄ can be preferably used.

Furthermore, for firing at about 600° C. after pattern formation, to evaporate the organic ingredient in the paste, the reaction between ITO and silver electrodes at high temperature must be taken into account. Though the detail of the reaction mechanism is not yet perfectly clarified, there are cases where the melting of silver particles on the surfaces is inhibited by release of oxygen and exchange of electrons at high temperature, depending on the black pigment used. The inhibition can be remarkably observed in the case where the black pigment contains Mn. Therefore, especially in view of good stability at high temperature, less reaction with silver and controllability of sintering of silver, it is preferred to use a Co—Cu based composite oxide alone or together with CO₃O₄.

In the case where a Co—Cu based composite oxide is used, in view of blackness, hue, thermal stability and electric stability, a composite oxide containing 30 to 70 wt % of Co and 5 to 30 wt % of Cu is preferred. If the Co content is less than 30 wt %, the particles are unevenly formed, and the dispersibility in the paste is very low to lower the pattern formability and to lower blackness accordingly. If the Co content is more than 70 wt %, the electric resistance is so high that the conduction between ITO and silver electrodes is destabilized. Further, in view of blackness, hue, thermoelectric stability and electric stability, it is preferred that any other metal element than Co and Cu is not substantially contained.

In view of the required properties of the black layer to be formed, CO₃O₄ and a Co—Cu based composite oxide can be used in combination. In this case, if the amount of CO₃O₄ is too large, a brownish black layer is formed. So, it is preferred to keep the CO₃O₄ content at less than 90 wt % of the pigment as a whole. It is more preferred to keep the content at less than 80 wt % of the pigment as a whole.

A pigment with a spinel structure refers to a compound having MgOAl₂O₃ crystal structure. If a divalent metal is A, a trivalent metal is B, and a tetravalent metal is C, then the compound can be represented by a chemical formula, AB₂O₄ or CB₂O₄, and AB₂O₄ is used as a stable pigment. Metal elements include Mg, Zn, Mn, Fe, Co, Ni, Cu, etc. A black pigment contains some of Fe, Co, Cr, Mn, Ni and Cu as main elements, and their contents decide crystal stability. In this invention, for obtaining the preferred blackness, hue, thermoelectric stability and electric stability as described above, a composite oxide containing Co element and at least one or more metal elements other than the Co element and having a spinel structure is important.

Whether or not the composite oxide constituting the black pigment has a spinel structure can be judged in reference to whether or not a diffraction pattern peculiar to a spinel structure can be observed in the observed X-ray diffraction pattern.

In view of the prevention of discoloration at high temperature, a black pigment composed of a composite oxide containing 5 to 50 wt % of Co is preferred, and a black pigment composed of a composite oxide containing 10 to 40 wt % of Co is more preferred.

Further, in view of the prevention of discoloration at high temperature and the dispersibility of the black pigment, a black pigment composed of a composite oxide containing 5 to 50 wt % of Co and 5 to 50 wt % of Cu is preferred, and a black pigment composed of a composite oxide containing 10 to 40 wt % of Co and 10 to 40 wt % of Cu is more preferred.

Furthermore, in view of the prevention of discoloration at high temperature and the dispersibility of the black pigment, a black pigment composed of a composite oxide containing 5 to 50 wt % of Co, 5 to 50 wt % of Cu and 5 to 50 wt % of Mn is preferred, and a black pigment composed of a composite oxide containing 10 to 40 wt % of Co, 10 to 40 wt % of Cu and 10 to 40 wt % of Mn is more preferred.

Moreover, as for a black pigment other than the above-mentioned black pigments, in view of the prevention of discoloration at high temperature and the dispersibility of the black pigment, a black pigment composed of a composite oxide containing 5 to 50 wt % of Co, 5 to 50 wt % of Ni and 5 to 50 wt % of Mn is preferred.

The contents of the respective metal components in the black pigment can be obtained by an analysis method such as inductively-coupled plasma (ICP) emission analysis or fluorescent X-ray analysis.

It is preferred that the average particle size Db of the black pigment is 0.01 to 0.5 μm, and a more preferred range is 0.02 to 0.3 μm. It is preferred that the average particle size of the black pigment is in the abovementioned range, since a light shielding layer with uniform and sufficient blackness can be formed. If the average particle size of the black pigment is less than 0.01 μm, the blackness tends to be uneven, since cohesion is likely to occur. If the average particle size is more than 0.5 μm, the blackness tends to decline. Meanwhile, in this invention, the average particle size refers to the 50% particle size of the volume distribution curve.

It is preferred that the specific surface area of the black pigment is 10 to 200 m²/g. A more preferred range is 20 to 100 m²/g. If the specific surface area of the black pigment is less than 10 m²/g, the blackness tends to decline, and if it is more than 200 m²/g, the blackness tends to be uneven since the cohesion is liable to occur.

It is preferred that the black pigment content is 5 to 40 wt % based on the total weight of the inorganic ingredients of the glass paste. A more preferred range is 10 to 30 wt %. If the content is less than 5 wt %, the blackness is insufficient, and there is a tendency that sufficient contrast cannot be obtained. If it is more than 40 wt %, the dielectric layer tends to contain bubbles because of poor pattern formability and an insufficient degree of sintering.

Further, in addition to the abovementioned black pigment, a black pigment such as carbon particles or ruthenium oxide can also be used together. It is preferred that the added amount of the additional black pigment is 0.1 to 3 wt % based on the total weight of the black pigments.

It is preferred that the glass powder used in this invention has a glass transition point of 400 to 490° C., and a more preferred range is 420 to 470° C. Furthermore, it is preferred that the glass powder has a softening point under load of 450 to 540° C., and a more preferred range is 470 to 520° C. If the glass transition point and the softening point under load are in these ranges, the formation of bubbles in the dielectric sintering step can be inhibited, since sufficient sintering can be achieved while the formed pattern can be maintained.

The average particle size Dg of the glass powder can be selected appropriately to suit each purpose, but it is preferred that the average particle size is 0.1 to 2.0 μm. A more preferred range is 0.3 to 1.0 μm. If the average particle size is less than 0.1 μm, the blackness tends to be uneven, since cohesion is liable to occur. If it is more than 2.0 μm, the pattern formability becomes low, and the degree of sintering at the time of firing tends to be insufficient.

Further, it is preferred that the average particle size Dg of the glass powder and the average particle size Db of the black pigment satisfy the following relation:

0.01<Db/Dg<0.9

It is more preferred that the following relation is satisfied:

0.1<Db/Dg<0.5

If Db/Dg is 0.01 or less, the particle size of the black pigment is so small that dispersion tends to be very difficult. If it is 0.9 or more, pattern formability declines, and the degree of sintering at the time of firing tends to be adversely affected.

Further, it is preferred that the maximum particle size of the glass powder is 20 μm or less, and more preferred is 10 μm or less. If the maximum particle size is more than 20 μm, the pattern formability declines and numerous particles larger than the film thickness exist, resulting in a tendency to adversely affect the electrode layer and the dielectric layer formed later by lamination.

Further, it is preferred that the maximum particle size Dtb of the black pigment and the maximum particle size Dtg of the glass powder satisfy the following relation:

0.05<Dtb/Dtg<0.5

It is more preferred that the following relation is satisfied:

0.1<Dtb/Dtg<0.4

If Dtb/Dtg is 0.05 or less, the particle size of the black pigment is so small as to result in a tendency to make dispersion very difficult. If it is 0.5 or more, the pattern formability declines, and there is a tendency to adversely affect the electrode layer and the dielectric layer formed later by lamination.

It is preferred that the specific surface area of the glass powder is 1 to 15 cm²/g, and a more preferred range is 2 to 10 cm²/g. If the specific surface area is less than 1 cm²/g, the pattern formability declines, and the degree of sintering at the time of firing tends to be insufficient. If it is more than 15 cm²/g, cohesion tends to be likely to be caused.

It is preferred that the glass powder content is 10 to 45 wt % based on the weight of the glass paste. A more preferred range is 15 to 40 wt %. If the glass powder content is less than 10 wt %, sintering tends to be insufficient, and if it is more than 45 wt %, the rate of the black pigment declines as a result in a tendency to lower the blackness.

The organic ingredient used in this invention is not especially limited, but a cellulose compound typified by ethyl cellulose or an acrylic polymer typified by polyisobutyl methacrylate, etc. can be used. Other examples of the organic ingredient include polyvinyl alcohol, polyvinyl butyral, methacrylic acid ester polymers, acrylic acid ester polymers, acrylic acid ester-methacrylic acid ester copolymers, α-methylstyrene polymer, butyl methacrylate resin, etc.

Further, as a method for forming a display member using the glass paste of this invention, in the case where a photolithography method is used, it is preferred to use a photosensitive organic ingredient as the organic ingredient. The photosensitive organic ingredient is at least one photosensitive organic ingredient selected from photosensitive monomers, photosensitive oligomers and photosensitive polymers, and as required, may further contain additive ingredients such as a photo polymerization initiator, ultraviolet light absorber, sensitizer, sensitizing aid, polymerization inhibitor, plasticizer, thickener, organic solvent, antioxidant, dispersing agent and organic or inorganic suspending agent.

A photosensitive monomer is a compound containing a carbon-carbon unsaturated bond. Examples of it include monofunctional and polyfunctional (meth)acrylates, vinyl based compounds, allyl based compounds, etc., particularly acrylates such as methyl acrylate, ethyl acrylate, n-propyl acrylate, isopropyl acrylate, n-butyl acrylate, sec-butyl acrylate, isobutyl acrylate, tert-butyl acrylate, n-pentyl acrylate, allyl acrylate, benzyl acrylate, butoxyethyl acrylate, butoxytriethylene glycol acrylate, cyclohexyl acrylate, dicyclopentanyl acrylate, dicyclopentenyl acrylate, 2-ethylhexyl acrylate, glycerol acrylate, glycidyl acrylate, heptadecafluorodecyl acrylate, 2-hydroxyethyl acrylate, isobonyl acrylate, 2-hydroxypropyl acrylate, isodecyl acrylate, isooctyl acrylate, lauryl acrylate, 2-methoxyethyl acrylate, methoxy ethylene glycol acrylate, methoxy diethylene glycol acrylate, octafluoropentyl acrylate, phenoxyethyl acrylate, stearyl acrylate, trifluoroethyl acrylate, allylated cyclohexyl diacrylate, 1,4-butanediol diacrylate, 1,3-butylene glycol diacrylate, ethylene glycol diacrylate, diethylene glycol diacrylate, triethylene glycol diacrylate, polyethylene glycol diacrylate, dipentaerythritol hexaacrylate, dipentaerythritol monohydroxy pentaacrylate, ditrimethylolpropane tetraacrylate, glycerol diacrylate, methoxylated cyclohexyl diacrylate, neopentyl glycol diacrylate, propylene glycol diacrylate, polypropylene glycol diacrylate, triglycerol diacrylate, trimethylolpropane triacrylate, acrylamide, aminoethyl acrylate, phenyl acrylate, phenoxyethyl acrylate, benzyl acrylate, 1-naphthyl acrylate, 2-naphthyl acrylate, bisphenol A diacrylate, diacrylate of bisphenol A-ethylene oxide addition product, diacrylate of bisphenol A-propylene oxide addition product, thiophenol acrylate, and benzyl mercaptan acrylate, further, monomers obtained by substituting one to five hydrogen atoms of the aromatic ring of the acrylates by chlorine atoms or bromine atoms, furthermore, styrene, p-methylstyrene, o-methylstyrene, m-methylstyrene, chlorinated styrene, brominated styrene, α-methylstyrene, chlorinated α-methylstyrene, brominated α-methylstyrene, chloromethylstyrene, hydroxymethylstyrene, carboxymethylstyrene, vinylnaphthalene, vinylanthracene, vinyl carbazole, those obtained by replacing some or all of the acrylates in the molecules of the abovementioned compounds by methacrylates, 7-methacryloxypropyl trimethoxysilane, 1-vinyl-2-pyrrolidone, etc. In this invention, any one of these photosensitive monomers can be used alone or two or more of them can also be used together.

In addition to the above compounds, if an unsaturated acid such as an unsaturated carboxylic acid is added, the developability after exposure can be enhanced. Examples of the unsaturated carboxylic acid include acrylic acid, methacrylic acid, itaconic acid, crotonic acid, maleic acid, fumaric acid, vinylacetic acid and their anhydrides, etc.

It is preferred that the content of any of these photosensitive monomers is 5 to 30 wt % based on the weight of the solid remaining after removing the solvent ingredient from the entire paste composition. It is not preferred that the photosensitive monomer content is not in this range, since otherwise the pattern formability declines while the hardness after curing becomes insufficient.

Further, as one of photosensitive oligomers or photosensitive polymers, an oligomer or polymer obtained by polymerizing at least one of the compounds respectively containing a carbon-carbon unsaturated bond can be used. It is preferred that the content of said compound containing a carbon-carbon unsaturated bond is 10 wt % or more based on the total weight of the photosensitive oligomers or photosensitive polymers. More preferred is 35 wt % or more. Further, it is preferred that an unsaturated acid such as an unsaturated carboxylic acid is copolymerized with the photosensitive oligomer or photosensitive polymer, since the developability after exposure can be enhanced. Examples of the unsaturated carboxylic acid include acrylic acid, methacrylic acid, itaconic acid, crotonic acid, maleic acid, fumaric acid, vinylacetic acid, and their anhydrides, etc. It is preferred that the oligomer or polymer having acid groups such as carboxyl groups at the side chains obtained as described above has an acid value (AV) of 30 to 150. A more preferred range is 70 to 120. If the acid value is less than 30, the solubility of the non-exposed area in the developer declines. If the developer concentration is enhanced, the exposed area is also peeled, and there is a tendency that a highly precise pattern is unlikely to be obtained. Further, if the acid value is more than 150, the development tolerance tends to be narrowed.

Any of these photosensitive oligomers and photosensitive polymers can have photo reactive groups added at the side chains or molecular ends, so that it can be used as a photosensitive oligomer or photosensitive polymer having photosensitivity. Preferred photo reactive groups include ethylenic unsaturated groups. Ethylenic unsaturated groups include vinyl groups, allyl group, acrylic groups, methacrylic groups, etc.

Such side chains can be added to an oligomer or polymer by a method of adding an ethylenic unsaturated compound with a glycidyl group or isocyanate group, acrylic acid chloride, methacrylic acid chloride or allyl chloride to the mercapto groups, amino groups, hydroxyl groups or carboxyl groups in the polymer for reaction.

Examples of the ethylenic unsaturated compound with a glycidyl group include glycidyl acrylate, glycidyl methacrylate, allyl glycidyl ether, glycidyl ethylacrylate, crotonyl glycidyl ether, glycidyl crotonate ether, glycidyl isocrotonate ether, etc.

Examples of the ethylenic unsaturated compound with an isocyanate group include (meth)acryloyl isocyanate, (meth)acryloylethyl isocyanate, etc.

Further, it is preferred that 0.05 to 1 mole equivalent of the ethylenic unsaturated compound with a glycidyl group or isocyanate group, acrylic acid chloride, methacrylic acid chloride or allyl chloride is added to the mercapto groups, amino groups, hydroxyl groups or carboxyl groups in the polymer.

It is preferred that the content of the photosensitive oligomer and/or the photosensitive polymer in the photosensitive glass paste is 5 to 30 wt % based on the weight of solid remaining after excluding the solvent ingredient from the entire paste composition in view of pattern formability and shrinkage after firing. It is not preferred that the content is not in this range, since the pattern cannot be formed or becomes large in element size.

Examples of the photo polymerization initiator include benzophenone, methyl o-benzoylbenzoate, 4,4′-bis(dimethylamino)benzophenone, 4,4′-bis(diethylamino)benzophenone, 4,4′-dichlorobenzophenone, 4-benzoyl-4-methyldiphenylketone, dibenzylketone, fluorenone, 2,2-diethoxyacetophenone, 2,2-dimethoxy-2-phenylacetophenone, 2-hydroxy-2-methylpropiophenone, p-t-butyldichloroacetophenone, thioxanthone, 2-methylthioxanthone, 2-chlorothioxanthone, 2-isopropylthioxanthone, diethylthioxanthone, benzyldimethylketanol, benzyldimethoxyethylacetal, benzoin, benzoin methyl ether, benzoin butyl ether, anthraquinone, 2-t-butylanthraquinone, 2-amylanthraquinone, β-chloroanthraquinone, anthrone, benzanthrone, dibenzosuberone, methyleneanthrone, 4-azidobenzalacetophenone, 2,6-bis(p-azidobenzylidene)cyclohexanone, 2,6-bis(p-azidobenzylidene)-4-methylcyclohexanone, 2-phenyl-1,2-butadione-2-(o-methoxycarbonyl)oxime, 1-phenyl-propanedione-2-(o-ethoxycarbonyl)oxime, 1,3-diphenyl-propanetrione-2-(o-ethoxycarbonyl)oxime, 1-phenyl-3-ethoxy-propanetrione-2-(o-benzoyl)oxime, Michler's ketone, 2-methyl[4-(methylthio)phenyl]-2-morpholino-1-propane, 2-benzyl-2-dimethylamino-1-(4-morpholinophenyl)butanone-1, naphthalenesulfonyl chloride, quinolinesulfonyl chloride, N-phenylthioacridone, 4,4′-azobisisobutyronitrile, diphenyl disulfide, benzthiazole disulfide, triphenylphosphine, camphorquinone, carbon tetrabromide, tribromophenylsulfone, benzoyl peroxide, photoreducing colorants such as Eosine and Methylene Blue, reducing agents such as ascorbic acid and triethanolamine, etc. In this invention, any one of them can be used alone or two or more of them can also be used together.

It is preferred that the added amount of the photo polymerization initiator is in a range from 0.05 to 20 wt % based on the weight of the photosensitive organic ingredient. A more preferred range is 0.1 to 15 wt %. If the amount of the photo polymerization initiator is less than 0.05 wt %, photosensitivity tends to be low, and if it is more than 20 wt %, the rate of the remaining exposed area tends to be too small.

A sensitizer is added for enhancing sensitivity. Examples of the sensitizer include 2,4-diethylthioxanthone, isopropylthioxanthone, 2,3-bis(4-diethylaminobenzal)cyclopentanone, 2,6-bis(4-dimethylaminobenzal)cyclohexanone, 2,6-bis(4-dimethylaminobenzal)-4-methylcyclohexanone, Michler's ketone, 4,4′-bis(diethylamino)-benzophenone, 4,4′-bis(dimethylamino)chalcone, 4,4′-bis(diethylamino)chalcone, p-dimethylaminocinnamylideneindanone, p-dimethylaminobenzylideneindanone, 2-(p-dimethylaminophenylvinylene)-isonaphthothiazole, 1,3-bis(4-dimethylaminobenzal)acetone, 1,3-carbonyl-bis(4-diethylaminobenzal)acetone, 3,3′-carbonyl-bis(7-diethylaminocumarine), N-phenyl-N-ethylethanolamine, N-phenylethanolamine, N-tolyldiethanolamine, N-phenylethanolamine, isoamyl dimethylaminobenzoate, isoamyl diethylaminobenzoate, 3-phenyl-5-benzoylthiotetrazole, 1-phenyl-5-ethoxycarbonylthiotetrazole, etc. In this invention, any one of them can be used alone or two or more of them can also be used together. Meanwhile, some of sensitizers can also be used as photo polymerization initiators. In the case where a sensitizer is added to the glass paste of this invention, it is preferred that the added amount of the sensitizer is usually 0.05 to 30 wt % based on the weight of the photosensitive organic ingredient. A more preferred range is 0.1 to 20 wt %. If the amount is less than 0.05 wt %, there is a tendency that the effect of enhancing photosensitivity is unlikely to be exhibited, and if it is more than 30 wt %, the rate of the remaining exposed area tends to be too small.

A polymerization inhibitor is added for enhancing the thermal stability during storage. Examples of the polymerization inhibitor include hydroquinone, monoesterification products of hydroquinone, N-nitrosodiphenylamine, phenothiazine, p-t-butylcatechol, N-phenylnaphthylamine, 2,6-di-t-butyl-p-methylphenol, chloranil, pyrogallol, p-methoxyphenol, etc. Further, if a polymerization inhibitor is added, the threshold value of photocuring reaction rises to prevent the shortening of the line width of a pattern and the thickening at the upper portion of a pattern toward a gap.

It is preferred that the added amount of the polymerization inhibitor is 0.01 to 1 wt % based on the weight of the glass paste. If the amount is less than 0.01 wt %, there is a tendency that the effect of addition is unlikely to be exhibited, and if it is more than 1 wt %, a larger exposure amount tends to be required for pattern formation, since the sensitivity declines.

Examples of the plasticizer include dibutyl phthalate, dioctyl phthalate, polyethylene glycol, glycerol, etc.

The antioxidant is added for preventing the oxidation of the acrylic copolymer during storage. Examples of the antioxidant include 2,6-di-t-butyl-p-cresol, butylated hydroxyanisole, 2,6-di-t-butyl-4-ethylphenol, 2,2′-methylene-bis(4-methyl-6-t-butylphenol), 2,2′-methylene-bis(4-ethyl-6-t-butylphenol), 4,4′-bis(3-methyl-6-t-butylphenol), 1,1,3-tris(2-methyl-4-hydroxy-6-t-butylphenyl)butane, bis[3,3-bis-(4-hydroxy-3-t-butylphenyl)butyric acid]glycol ester, dilauryl thiodipropionate, triphenyl phosphite, etc. In the case where an antioxidant is added, it is preferred that the added amount of the antioxidant is 0.01 to 1 wt % based on the weight of the glass paste.

An organic solvent may also be added to the glass paste of this invention for adjusting the viscosity of the solution. Examples of the organic solvent used include methyl cellosolve, ethyl cellosolve, butyl cellosolve, methyl ethyl ketone, dioxane, acetone, cyclohexanone, cyclopentanone, isobutyl alcohol, isopropyl alcohol, tetrahydrofuran, dimethyl sulfoxide, γ-butyrolactone, bromobenzene, chlorobenzene, dibromobenzene, dichlorobenzene, bromobenzoic acid, chlorobenzoic acid, terpineol, diethylene glycol monobutyl ether acetate, etc., and an organic solvent mixture containing at least one or more of the foregoing.

The glass paste of this invention is usually produced by mixing at least one of said photosensitive monomers, photosensitive oligomers and photosensitive polymers, further as required, additive ingredients such as a photo polymerization initiator, ultraviolet light absorber, sensitizer, sensitizing aid, polymerization inhibitor, plasticizer, thickener, organic solvent, antioxidant, dispersing agent and organic or inorganic suspending agent, to achieve a predetermined composition and homogeneously dispersing using a three-roller mill or kneading machine.

The viscosity of the glass paste can be appropriately adjusted, but a preferred range of viscosity is 0.2 to 200 Pa·s. For example, in the case where a spin coating method is used for coating a glass substrate, a range from 0.2 to 5 Pa·s is more preferred, and in the case where a screen printing method is used for obtaining a film thickness of 10 to 20 μm by one time of coating, a range from 10 to 100 Pa·s is more preferred.

It is preferred that the ratio by weight of glass powder:organic ingredient excluding the solvent ingredient is 20:80 to 60:40. Amore preferred range is 30:70 to 50:50. If the amount of the organic ingredient is less than 40 wt %, the pattern formability tends to decline, and if it is more than 80 wt %, there is a tendency that a desired film thickness is unlikely to be obtained.

Further, additives such as metal powder may also be added to the glass paste of this invention to such an extent that the effect of this invention is not impaired. Examples of the metal powder include the powder of Au, Ag, Pt, Cu, Ni, Cr, Co, etc. Also in this case, considering the environmental impact, it is preferred not to use Cr.

The glass paste of this invention can be applied to an ITO pattern for use as black electrodes. Further, it can also be used as a black layer between an ITO pattern and a silver electrode pattern, or can also be used as a black stripe layer serving to cover the non-light-emitting portions or as a black matrix layer. In any case, it can enhance the contrast of the display screen.

Further, this invention relates to a display production process comprising the step of coating and drying said glass paste, for forming a paste coating film, the step of exposing the paste coating film through a photo mask, the step of developing the exposed paste coating film, and the step of forming a pattern by firing.

The method for forming a paste coating film is not especially limited, but a photolithography method or screen-printing method is preferred. In view of excellence in high precision and simple process, a photolithography method is more preferred.

Next, an example of forming a paste coating film using a photosensitive paste method is explained below, but this invention is not limited thereto or thereby.

A glass substrate or a ceramic substrate, or a polymeric film is coated entirely or partially with a photosensitive glass paste. The coating method can be any general method such as a screen-printing method or use of a bar coater, roll coater, die coater, or blade coater. The coating thickness can be adjusted by selecting the coating times, screen mesh size and paste viscosity. Further, a method comprising the steps of coating a film such as a polyester film with a photosensitive glass paste to prepare a photosensitive sheet, and transferring the photosensitive glass paste onto a substrate using a device such as a laminator can also be used.

The coating of a photosensitive glass paste is followed by exposure using an exposure device. A method of exposing through a photo mask as practiced in ordinary photolithography is a general exposure method. The mask used is a negative or positive mask selected depending on the photosensitive organic ingredient used. Further, without using a photo mask, a method of using a red or blue laser beam or the like for direct drawing can also be used.

The exposure apparatus used can be an exposure stepper or proximity exposure apparatus, etc. Further, for exposing a large area, after a substrate such as a glass substrate is coated with a photosensitive glass paste, the coated substrate can be carried and be moved during exposure, so that an exposure apparatus with a small exposure area can be used to expose a large area. Examples of the active light source used include visible radiation, near ultraviolet radiation, ultraviolet radiation, electron beam, X-radiation, laser beam, etc. Among them, ultraviolet radiation is most preferred, and examples of the light source include a low-pressure mercury lamp, high-pressure mercury lamp, ultra-high pressure mercury lamp, halogen lamp, germicidal lamp, etc. Among them, an ultra-high pressure mercury lamp is suitable. The exposure conditions depend on the coating thickness, but usually exposure is performed using an ultra-high pressure mercury lamp with an output of 1 to 100 mW/cm² for 0.1 to 10 minutes.

After completion of exposure, development is performed using the difference between the solubility of the exposed portions in the developer and the solubility of the non-exposed portions in the developer, and in this case, an immersion method, shower method, spray method or brush method can be used.

The developer used is a solution into which the organic ingredient to be dissolved of the photosensitive glass paste can be dissolved. Further, water can also be added to the organic solvent to such an extent that the dissolving power of the organic solvent is not lost. In the case where a compound with an acid group such as a carboxyl group exists in the photosensitive glass paste, an alkali aqueous solution can be used for development. As the alkali aqueous solution, sodium hydroxide aqueous solution, sodium carbonate aqueous solution or calcium hydroxide aqueous solution, etc. can be used, but it is preferred to use an organic alkali aqueous solution, since the alkali ingredient can be easily removed at the time of firing. As the organic alkali, a general amine compound can be used. Examples of the amine compound include tetramethylammonium hydroxide, trimethylbenzylammonium hydroxide, monoethanolamine or diethanolamine, etc. It is preferred that the concentration of the alkali aqueous solution is 0.01 to 10 wt %, and a more preferred range is 0.1 to 5 wt %. If the concentration of the alkali aqueous solution is less than 0.01 wt %, there is a tendency that the soluble area is not removed, and if it is more than 10 wt %, the pattern is peeled, while there is a tendency that the non-soluble area is corroded. Further, in view of process control, it is preferred that the development temperature is 20 to 50° C.

Next, a firing furnace is used for firing. The firing atmosphere and temperature depend on the paste and the substrate used, but firing is performed in an atmosphere of air, nitrogen or hydrogen, etc. As the firing furnace, either a batch firing furnace or a belt-type continuous firing furnace can be used. The firing temperature is usually 400 to 1000° C. In the case where a pattern is formed on a glass substrate, firing is usually performed with the temperature kept at 450 to 620° C. for 10 to 60 minutes. Meanwhile, though the firing temperature depends on the glass powder used, it is preferred that firing is performed at such an appropriate temperature that the pattern form is not deformed and that the shape of the glass powder does not remain.

Further, among the above respective steps of coating, exposure, development and firing, heating steps of 50 to 300° C. can also be introduced for the purposes of drying and preliminary reaction.

The display of this invention obtained by the aforementioned production process is higher in display contrast, lower in reactive power and more stable electrically, since the glass paste of this invention containing a specific black pigment is used.

### EXAMPLES

This invention is explained below in reference to examples, but is not limited thereto or thereby.

### (Measurement of L* Value, a* Value and b* Value)

The L* value, a* value and b* value of a front panel having up to a dielectric layer formed were measured from both the glass surface side and the dielectric layer surface side using a spectrophotometric calorimeter (CM-2002 produced by Minolta Co., Ltd.). Three substrates were measured at three points per substrate, and the values of the nine points were averaged to obtain each measured value.

### (Evaluation of Discoloration)

Based on the* value and the b* value obtained in the above, the saturation c* was obtained from the following formula:

c*={(a* value)²+(b* value)²}^{1/2}

In the case where discoloration is caused by the heat during firing, there arise such problems that L value becomes large and that the saturation c* becomes large. So, the degree of discoloration was judged according to the following criterion.
Double circle: L value is less than 10 and saturation is less than 2.0.
Single circle: L value is 10 to less than 15 and saturation is less than 3.0, or L value is less than 15 and saturation is 2.0 to less than 3.0.
Cross: L value is 15 or more or saturation is 3.0 or more.

### (Specific Resistance of Electrode)

With a PDP prepared in an example, the resistance value, thickness and line width of a bus electrode were measured to obtain the resistance of the electrode.

### (Contrast Measurement)

With a PDP prepared in an example, the emitted display light (La), reflected light (Lr) and emitted background light (Lb) under illumination of 150 1× were measured, and the photopic contrast was calculated from the following formula:

(Photopic contrast)=(La+Lr)/(Lb+Lr)

A contrast value of 100 or less does not allow use because of low visual quality.

### (Measurement of Reactive Power)

With the sustaining discharge voltage of a front panel as 180 V and frequency as 30 kHz, the current value was measured, and the reactive power was calculated.

### (Softening Point Under Load)

A differential thermal analyzer produced by Rigaku Corporation was used to measure the softening point under load.

### Production Example 1

### Production of Photosensitive Silver Paste for Front Substrate

Seventy parts by weight of silver powder with an average particle size of 2.0 μm, 2 parts by weight of a glass powder with an average particle size of 2.2 μm consisting of 65 wt % of bismuth oxide, 28 wt % of silicon oxide, 4 wt % of aluminum oxide and 3 wt % of boron oxide, 8 parts by weight of a copolymer consisting of acrylic acid, methyl methacrylate and styrene, 7 parts by weight of trimethylolpropane triacrylate, 3 parts by weight of benzophenone, 7 parts by weight of butyl carbitol acetate and 3 parts by weight of benzyl alcohol were mixed using a three-roller mill, to produce a photosensitive silver paste.

### Production Example 2

### Paste for Forming Barrier Ribs

Sixty seven parts by weight of a glass powder (average particle size 2 μm) consisting of Bi₂O₃/SiO₂/Al₂O₃/ZnO/B₂O₃/BaO=40/10/5/15/15/15 (wt %), 10 parts by weight of a polymer (Cyclomer-P ACA250, produced by Daicel Chemical Industries, Ltd.), 10 parts by weight of trimethylolpropane triacrylate, 3 parts by weight of 2-methyl-1-4-methylthiophenyl-2-2-morpholinopropane-1-one, 3 parts by weight of titanium oxide (average particle size 0.2 μm), 4 parts by weight of benzyl alcohol and 3 parts by weight of butyl carbitol acetate were added together, and then mixed and dispersed using a three-roller mill, to obtain a paste for forming barrier ribs.

### Working Examples 1 to 27 and Comparative Examples 1 to 3

In each example, a black pigment composed of the composite oxide(s) with a composition(s) shown in Table 1 and the amounts of the following additives shown in Tables 2 and 3 were mixed using a three-roller mill, to prepare a glass paste including a black pigment. Meanwhile, the contents of the respective metal components in the black pigment were obtained using both inductively-coupled plasma (ICP) emission analysis and fluorescent X-ray analysis. Further, X-ray diffraction images were observed according to JIS K 0131 (2002), and black pigments A through I and O through T respectively showed a diffraction pattern peculiar to spinel structure. As each black pigment, sulfates of respective metals were mixed, stirred and dissolved in purified water of about 50° C. at a ratio to achieve the final oxide rate. Further, about 4 wt % sodium hydroxide aqueous solution and a pigment salt aqueous solution were mixed at a ratio of 1:1. Subsequently, aeration was performed, and the mixture was kept at 90° C. for 1 hour. Then, diluted sulfuric acid was added to adjust pH to about 7, and the mixture was stirred for 1 hour. The solution was filtered, and the residue was washed and dried at 100° C. for 8 hours, then being fired at 600° C. for 2 hours, to obtain any of various composite oxide pigments.

Glass powder L: Bi₂O₃/SiO₂/Al₂O₃/ZnO/ZrO₂/B₂O₃=65/10/5/5/5/10 (wt %) average particle size 0.5 μm, glass transition point 450° C., softening point under load 490° C., maximum particle size 2.0 μm, specific surface area 7.0 cm²/g
Glass powder M: Bi₂O₃/SiO₂/Al₂O₃/ZnO/ZrO₂/B₂O₃=65/10/5/5/5/10 (wt %) average particle size 1.0 μm, glass transition point 455° C., softening point under load 495° C., maximum particle size 3.0 μm, specific surface area 5.5 cm²/g
Glass powder N: Bi₂O₃/SiO₂/Al₂O₃/ZnO/ZrO₂/B₂O₃=65/10/5/5/5/10 (wt %) average particle size 2.00 μm, glass transition point 462° C., softening point under load 500° C., maximum particle size 18 μm, specific surface area 2.2 cm²/g
Ag powder: Average particle size 2.0 μm
Ni powder: Average particle size 2.0 μm
Polymer: Photosensitive acrylic polymer with an acid value of 85 and Mw of 32,000 (APX-716 produced by Toray Industries, Inc.)
Photosensitive monomer: Propylene oxide modified trimethylolpropane triacrylate (produced by Dai-Ichi Kogyo Seiyaku Co., Ltd.)
Photo polymerization initiator 1: 2-benzyl-2-dimethylamino-1-(4-morpholinophenyl)-butanone-1 (IC-369 produced by Ciba Specialty Chemicals K.K.)
Photo polymerization initiator 2: 4,4′-bis(diethylamino)benzophenone
Sensitizer: 2,4-diethylthioxanthone (DETX-S produced by Nippon Kayaku Co., Ltd.)
Dispersing agent: Polyether ester type anionic surfactant (“Disparon” 7004, produced by Kusumoto Chemicals, Ltd.)
Polymerization inhibitor: p-methoxyphenol
Organic solvent: Diethylene glycol monobutyl ether acetate

The front panel and the rear panel of a 42″ AC plasma display panel were formed and evaluated. The forming methods are sequentially explained below.

For forming the front panel, a 42″ PD-200 of 980×554×2.8 mm (produced by Asahi Glass Co., Ltd.) was used as the glass substrate. ITO was formed by a sputtering method, and subsequently a resist was coated, followed by exposure and development treatment. Etching treatment was performed to obtain transparent electrodes with a thickness of 0.1 μm and a line width of 200 μm.

In succession, said photosensitive glass paste containing a black pigment was coated on the substrate by screen-printing, and dried, followed by exposure through a photo mask.

The exposed black paste coating film was coated with a photosensitive silver paste by screen printing, followed by drying, exposing through a predetermined photo mask, and development, to form an unfired pattern. After completion of pattern formation, firing was performed at 570° C. for 15 minutes or IR drying was performed at 190° C. for 10 minutes.

Then, 70 parts by weight of a glass powder with a low melting point containing 70 wt % of bismuth oxide, 10 wt % of silicon oxide, 5 wt % of aluminum oxide, 5 wt % of zinc oxide and 10 wt % of boron oxide, 20 parts by weight of ethyl cellulose and 10 parts by weight of terpineol were kneaded to obtain a glass paste, and it was coated by screen printing to cover the bus electrodes of the display portions, to achieve a thickness of 50 μm, followed by firing at 570° C. for 15 minutes, to form a transparent dielectric.

On the substrate with a dielectric formed, a 0.5 μm thick magnesium oxide layer was formed as a protective film by electron beam evaporation, to prepare a front panel.

The method for forming the rear panel is explained below.

A 42″ PD-200 of 590×964×2.8 mm (produced by Asahi Glass Co., Ltd.) was used as a glass substrate. The substrate was coated with the photosensitive silver paste for a rear substrate obtained in Production Example 1 by screen-printing as write electrodes, followed by drying. Exposure through a predetermined photo mask was performed predetermined times, followed by development, to form an unfired pattern. After completion of pattern formation, firing was performed at 590° C. for 15 minutes.

The substrate was coated with a dielectric paste consisting of 60 parts by weight of a glass powder with a low melting point containing 78 wt % of bismuth oxide, 14 wt % of silicon oxide, 3 wt % of aluminum oxide, 3 wt % of zinc oxide and 2 wt % of boron oxide, 10 parts by weight of titanium oxide powder with an average particle size of 0.3 μm, 2 parts by weight of ethyl cellulose, 20 parts by weight of trimethylolpropane triacrylate, 0.5 part by weight of benzoyl peroxide and 15 parts by weight of terpineol, followed by drying.

The paste for forming barrier ribs obtained in Production Example 2 was coated to achieve a predetermined thickness using a die coater, followed by drying using a clean oven at 100° C. for 40 minutes to form a coating film. The formed coating film was exposed with a gap of 150 μm kept from a predetermined photo mask.

The barrier ribs formed like this were coated with phosphor pastes of respective colors using a screen-printing method, followed by firing (500° C., 30 minutes), to form a phosphor layer on the lateral faces of the barrier ribs and on the bottoms.

The obtained rear panel and the aforementioned front panel were stuck to each other for sealing, and a discharge gas was sealed in. A drive circuit was bonded to prepare a plasma display panel (PDP).

Table 4 shows the details of the black pastes, evaluation results of the quality properties of the front panels, and evaluation results of the PDP display quality obtained in Working Examples 1 through 27 and Comparative Examples 1 through 3.

TABLE 1

| | | | Average | Specific | Maximum |
|---|---|---|---|---|---|
| | | | particle | surface | particle |
| Black | Composition | Spinel | size | area | size |
| Pigment | (Content: wt %) | structure* | (μm) | (m²/g) | (μm) |
| A | Co/Mn/Cu/O | Contained | 0.1 | 20 | 0.7 |
| | (=25/25/15/35) | | | | |
| B | Co/Mn/Cu/O | Contained | 1.0 | 11 | 2.4 |
| | (=25/25/15/35) | | | | |
| C | Co/Mn/Cu/O | Contained | 0.1 | 15 | 0.7 |
| | (=35/20/10/35) | | | | |
| D | Co/Mn/Ni/O | Contained | 0.06 | 30 | 0.8 |
| | (=25/25/15/35) | | | | |
| E | Co/Mn/Ni/O | Contained | 0.02 | 250 | 1.4 |
| | (=25/25/15/35) | | | | |
| F | Co/Mn/O | Contained | 0.1 | 18 | 0.7 |
| | (=40/30/30) | | | | |
| G | Co/Cu/Fe/O | Contained | 0.08 | 24 | 0.6 |
| | (=30/20/5/45) | | | | |
| H | Co/Mn/Cu/Ni/O | Contained | 0.1 | 17 | 0.7 |
| | (=25/25/10/5/35) | | | | |
| I | Co/O | Contained | 0.04 | 50 | 2.1 |
| | (=70/30) | | | | |
| J | Cr/Mn/Fe/O | none | 0.1 | 20 | 1.5 |
| | (=20/20/25/35) | | | | |
| K | Heat resistant | none | 0.05 | 45 | 1.0 |
| | carbon black | | | | |
| O | Co/Cu/O | Contained | 0.1 | 20 | 0.8 |
| | (=50/25/25) | | | | |
| P | Co/Cu/O | Contained | 0.1 | 20 | 0.8 |
| | (=72/3/25) | | | | |
| Q | Co/Cu/O | Contained | 0.1 | 20 | 0.8 |
| | (=25/50/30) | | | | |
| R | Co/O | Contained | 0.1 | 20 | 0.8 |
| | (=70/30) | | | | |
| S | Co/Cu/O | Contained | 1.0 | 10 | 2.5 |
| | (=50/25/25) | | | | |
| T | Co/Cu/O | Contained | 0.02 | 280 | 0.5 |
| | (=50/25/25) | | | | |

*“Contained” expresses that a diffraction pattern peculiar to a spinel structure can be observed in the observed X-ray diffraction pattern and “none” expresses that it can't be observed.

TABLE 2

| | | | Example | | | | | | | | | | | |
|---|---|---|---|---|---|---|---|---|---|---|---|---|---|---|
| | | | 1 | 2 | 3 | 4 | 5 | 6 | 7 | 8 | 9 | 10 | 11 | 12 |
| Amount | Black | A | 10 | 15 | 10 | 4 | — | — | — | — | — | — | — | — |
| (parts | pigment | B | — | — | — | — | 10 | 10 | — | — | — | — | — | — |
| by | | C | — | — | — | — | — | — | 10 | — | — | — | — | — |
| weight) | | D | — | — | — | — | — | — | — | 10 | — | — | — | — |
| | | E | — | — | — | — | — | — | — | — | 10 | — | — | — |
| | | F | — | — | — | — | — | — | — | — | — | 10 | — | — |
| | | G | — | — | — | — | — | — | — | — | — | — | 10 | — |
| | | H | — | — | — | — | — | — | — | — | — | — | — | 10 |

| | | | | | | | | | | | | |
|---|---|---|---|---|---|---|---|---|---|---|---|---|
| Glass powder L | 20 | 15 | 20 | 26 | 20 | 20 | 20 | 20 | 20 | 20 | 20 | 20 |
| Ag powder | — | — | 0.01 | — | — | — | — | — | — | — | — | — |
| Ni powder | — | — | — | — | — | 0.01 | — | — | — | — | — | — |
| Polymer | 16 | 16 | 16 | 16 | 16 | 16 | 16 | 16 | 16 | 16 | 16 | 16 |
| Photosensitive | 9 | 9 | 9 | 9 | 9 | 9 | 9 | 9 | 9 | 9 | 9 | 9 |
| monomer | | | | | | | | | | | | |
| Photo | 2 | 2 | 2 | 2 | — | 2 | 2 | 2 | 2 | — | 2 | 2 |
| polymerization | | | | | | | | | | | | |
| initiator 1 | | | | | | | | | | | | |
| Photo | — | — | — | — | 2 | — | — | — | — | 2 | — | — |
| polymerization | | | | | | | | | | | | |
| initiator 2 | | | | | | | | | | | | |
| Sensitizer | 2 | 2 | 2 | 2 | 2 | 2 | 2 | 2 | 2 | 2 | 2 | 2 |
| Dispersing agent | 1 | 1 | 1 | 1 | 1 | 1 | 1 | 1 | 1 | 1 | 1 | 1 |
| Polymerization | 0.5 | 0.5 | 0.5 | 0.5 | 0.5 | 0.5 | 0.5 | 0.5 | 0.5 | 0.5 | 0.5 | 0.5 |
| inhibitor | | | | | | | | | | | | |
| Organic solvent | 30 | 30 | 30 | 30 | 30 | 30 | 30 | 30 | 30 | 30 | 30 | 30 |

| | | | | | | | | | | | | |
|---|---|---|---|---|---|---|---|---|---|---|---|---|
| Viscosity (Pa · s) | 30 | 28 | 31 | 32 | 30 | 30 | 27 | 30 | 30 | 31 | 32 | 33 |

TABLE 3

| | | | Example | | | | | | | | | | | | | | |
|---|---|---|---|---|---|---|---|---|---|---|---|---|---|---|---|---|---|
| | | | 13 | 14 | 15 | 16 | 17 | 18 | 19 | 20 | 21 | 22 | 23 | 24 | 25 | 26 | 27 |
| Amount | Black | A | 10 | — | — | 10 | 10 | 10 | — | — | — | — | — | — | — | — | — |
| (parts | pigment | B | — | 10 | — | — | — | — | — | 9 | — | — | — | — | — | — | — |
| by | | C | — | — | 10 | — | — | — | 10 | — | — | — | — | — | — | — | — |
| weight) | | I | — | — | — | — | — | — | — | 1 | — | — | — | — | — | — | — |
| | | J | — | — | — | — | — | — | — | — | — | — | — | — | — | — | — |
| | | K | — | — | — | — | — | 0.1 | 0.1 | — | — | — | — | — | — | — | — |
| | | O | — | — | — | — | — | — | — | — | 10 | — | — | 3 | 2 | — | — |
| | | P | — | — | — | — | — | — | — | — | — | 10 | — | — | — | — | — |
| | | Q | — | — | — | — | — | — | — | — | — | — | 10 | — | — | — | — |
| | | R | — | — | — | — | — | — | — | — | — | — | — | 7 | 8 | — | — |
| | | S | — | — | — | — | — | — | — | — | — | — | — | — | — | 10 | — |
| | | T | — | — | — | — | — | — | — | — | — | — | — | — | — | — | 10 |

| | | | | | | | | | | | | | | | |
|---|---|---|---|---|---|---|---|---|---|---|---|---|---|---|---|
| Glass powder L | — | — | — | — | — | 20 | 20 | 20 | 20 | 20 | 20 | 20 | 20 | 20 | 20 |
| Glass powder M | 20 | 20 | 20 | — | — | — | — | — | — | — | — | — | — | — | — |
| Glass powder N | — | — | — | 20 | 20 | — | — | — | — | — | — | — | — | — | — |
| Ni powder | 0.01 | 0.01 | — | 0.01 | — | — | — | — | — | — | — | — | — | — | — |
| Polymer | 16 | 16 | 16 | 16 | 16 | 16 | 16 | 16 | 16 | 16 | 16 | 16 | 16 | 16 | 16 |
| Photosensitive | 9 | 9 | 9 | 9 | 9 | 9 | 9 | 9 | 9 | 9 | 9 | 9 | 9 | 9 | 9 |
| monomer | | | | | | | | | | | | | | | |
| Photo | 2 | 2 | 2 | 2 | — | 2 | 2 | 2 | 2 | 2 | 2 | 2 | 2 | 2 | 2 |
| polymerization | | | | | | | | | | | | | | | |
| initiator 1 | | | | | | | | | | | | | | | |
| Photo | — | — | — | — | 2 | — | — | — | — | — | — | — | — | — | — |
| polymerization | | | | | | | | | | | | | | | |
| initiator 2 | | | | | | | | | | | | | | | |
| Sensitizer | 2 | 2 | 2 | 2 | 2 | 2 | 2 | 2 | 2 | 2 | 2 | 2 | 2 | 2 | 2 |
| Dispersing agent | 0.5 | 0.5 | 0.5 | 0.5 | 0.5 | 0.5 | 0.5 | 0.5 | 0.5 | 0.5 | 0.5 | 0.5 | 0.5 | 0.5 | 0.5 |
| Polymerization | 0.01 | 0.01 | 0.01 | 0.01 | 0.01 | 0.01 | 0.01 | 0.01 | 0.01 | 0.01 | 0.01 | 0.01 | 0.01 | 0.01 | 0.01 |
| inhibitor | | | | | | | | | | | | | | | |
| Organic solvent | 30 | 30 | 30 | 30 | 30 | 30 | 30 | 30 | 30 | 30 | 30 | 30 | 30 | 30 | 30 |

| | | | | | | | | | | | | | | | |
|---|---|---|---|---|---|---|---|---|---|---|---|---|---|---|---|
| Viscosity (Pa · s) | 32 | 36 | 34 | 32 | 33 | 29 | 33 | 33 | 31 | 33 | 32 | 33 | 33 | 28 | 39 |

TABLE 4

| | | | Comparative example | | |
|---|---|---|---|---|---|
| | | | 1 | 2 | 3 |
| Amount | Black | A | — | — | — |
| (parts | pigment | B | — | — | — |
| by | | C | — | — | — |
| weight) | | I | 10 | 15 | — |
| | | J | — | — | 10 |
| | | K | — | — | — |
| | | O | — | — | — |
| | | P | — | — | — |
| | | Q | — | — | — |
| | | R | — | — | — |

| | | | |
|---|---|---|---|
| Glass powder L | 20 | 15 | 20 |
| Glass powder M | — | — | — |
| Glass powder N | — | — | — |
| Ni powder | — | — | — |
| Polymer | 16 | 16 | 16 |
| Photosensitive | 9 | 9 | 9 |
| monomer | | | |
| Photo polymerization | 2 | — | 2 |
| initiator 1 | | | |
| Photo polymerization | — | 2 | — |
| initiator 2 | | | |
| Sensitizer | 2 | 2 | 2 |
| Dispersing agent | 0.5 | 0.5 | 0.5 |
| Polymerization | 0.01 | 0.01 | 0.01 |
| inhibitor | | | |
| Organic solvent | 30 | 30 | 30 |

| | | | |
|---|---|---|---|
| Viscosity (Pa · s) | 32 | 32 | 33 |

TABLE 5

| | | | | | | Resistivity of | Daylight | Reactive |
|---|---|---|---|---|---|---|---|---|
| | | | | | Degree of | electrode | room | power |
| | L* value | a* value | b* value | Saturation c* | browning | (μΩ · cm) | contrast | (W) |
| Example 1 | 6 | −0.4 | −0.5 | 0.6 | ⊚ | 4.3 | 180 | 45 |
| Example 2 | 11 | −0.3 | −0.7 | 0.8 | ◯ | 4.4 | 140 | 52 |
| Example 3 | 6 | 0.2 | 1.5 | 1.5 | ⊚ | 4.1 | 180 | 40 |
| Example 4 | 13 | −0.6 | −0.1 | 0.6 | ◯ | 4.6 | 105 | 41 |
| Example 5 | 14 | −0.5 | −0.5 | 0.7 | ◯ | 4.3 | 100 | 44 |
| Example 6 | 14 | −0.1 | −0.9 | 0.9 | ◯ | 4.1 | 100 | 42 |
| Example 7 | 5 | −1.2 | −1.5 | 1.9 | ⊚ | 4.0 | 180 | 48 |
| Example 8 | 6 | −0.8 | 0.1 | 0.8 | ⊚ | 4.3 | 170 | 45 |
| Example 9 | 10 | −0.8 | 0.3 | 0.9 | ◯ | 4.3 | 120 | 45 |
| Example 10 | 10 | 0.2 | 0.4 | 0.4 | ◯ | 4.5 | 110 | 46 |
| Example 11 | 9 | 0.1 | 0.4 | 0.4 | ⊚ | 3.9 | 120 | 46 |
| Example 12 | 6 | −0.5 | −0.8 | 0.9 | ⊚ | 4.3 | 180 | 41 |
| Example 13 | 8 | −0.4 | −0.5 | 0.6 | ⊚ | 4.1 | 180 | 46 |
| Example 14 | 13 | −0.4 | −0.6 | 0.7 | ◯ | 4.4 | 130 | 47 |
| Example 15 | 7 | −0.8 | −1.2 | 1.4 | ⊚ | 4.0 | 160 | 48 |
| Example 16 | 10 | −0.9 | −1.0 | 1.3 | ◯ | 4.1 | 130 | 43 |
| Example 17 | 11 | −0.9 | −1.0 | 1.3 | ◯ | 4.3 | 130 | 48 |
| Example 18 | 5 | −0.9 | −1.1 | 1.4 | ⊚ | 4.2 | 190 | 42 |
| Example 19 | 5 | −1.1 | −2.0 | 2.3 | ◯ | 3.9 | 190 | 47 |
| Example 20 | 12 | −0.1 | 0.1 | 0.1 | ◯ | 4.2 | 120 | 42 |
| Example 21 | 4 | −0.5 | −1.0 | 1.1 | ⊚ | 3.6 | 190 | 48 |
| Example 22 | 10 | −0.2 | −0.2 | 0.3 | ◯ | 3.9 | 140 | 43 |
| Example 23 | 6 | −0.8 | −0.8 | 1.1 | ⊚ | 3.6 | 170 | 50 |
| Example 24 | 9 | 0.1 | 0.1 | 0.1 | ⊚ | 3.6 | 160 | 42 |
| Example 25 | 9 | 0.2 | 0.1 | 0.2 | ⊚ | 3.7 | 150 | 41 |
| Example 26 | 10 | −0.3 | −0.9 | 0.9 | ◯ | 3.7 | 150 | 48 |
| Example 27 | 12 | −0.2 | −0.6 | 0.6 | ◯ | 3.7 | 140 | 48 |
| Comparative | 19 | 2.1 | 1.2 | 2.4 | X | 3.8 | 70 | 50 |
| example 1 | | | | | | | | |
| Comparative | 17 | 2.9 | 1.5 | 3.3 | X | 3.8 | 80 | 55 |
| example 2 | | | | | | | | |
| Comparative | 16 | −0.1 | 0.1 | 0.1 | X | 4.3 | 90 | 48 |
| example 3 | | | | | | | | |

The front panels obtained in Working Examples 1 through 27 could have good electrode patterns formed by patterning. The L*, a* and b* values of the front panels were measured, and good results could be obtained. Furthermore, the contrast values and reactive power values of the PDPs were measured, and they were good in Working Examples through 27. Comparative Examples 1 through 3 were poor at least in any one of electrode patterning, L*, a* and b* values of front panel, contrast of PDP and reactive power.

1. A glass paste containing a black pigment, glass powder and organic ingredient, wherein the black pigment is a black pigment composed of a composite oxide containing Co element and one or more metal elements other than the Co element and having a spinel structure.

2. The glass paste, according to claim 1, wherein the black pigment is a black pigment composed of one or more composite oxides selected from the group consisting of a Co—Mn based composite oxide, Co—Cu—Fe based composite oxide, Co—Mn—Fe based composite oxide, Co—Cu—Mn based composite oxide, Co—Ni—Mn based composite oxide, Co—Ni—Fe—Mn based composite oxide and Co—Ni—Cu—Mn based composite oxide.

3. The glass paste, according to claim 1, wherein the black pigment is a Co—Cu based composite oxide.

4. The glass paste, according to claim 3, wherein the Co—Cu based composite oxide is a black pigment composed of a composite oxide containing 30 to 70 wt % of Co and 5 to 30 wt % of Cu.

5. The glass paste, according to claim 1, wherein the average particle size of the black pigment is 0.01 to 0.5 μm.

6. The glass paste, according to claim 1, wherein the black pigment is a black pigment composed of a composite oxide containing 5 to 50 wt % of Co.

7. The glass paste, according to claim 6, wherein the black pigment is a black pigment composed of a composite oxide containing 5 to 50 wt % of Co and 5 to 50 wt % of Cu.

8. The glass substrate, according to claim 7, wherein the black pigment is a black pigment composed of a composite oxide containing 5 to 50 wt % of Co, 5 to 50 wt % of Cu and 5 to 50 wt % of Mn.

9. The glass paste, according to claim 6, wherein the black pigment is a black pigment composed of a composite oxide containing 5 to 50 wt % of Co, 5 to 50 wt % of Ni and 5 to 50 wt % of Mn.

10. The glass paste, according to claim 1, wherein the specific surface area of the black pigment is 10 to 200 m²/g.

11. The glass paste, according to claim 1, wherein the average particle size Dg of the glass powder and the average particle size Db of the black pigment satisfy the following relation:
0.01<Db/Dg<0.9

12. The glass paste, according to claim 1, wherein the black pigment is contained by 5 to 40 wt % based on the weight of the inorganic powder.

13. The glass paste, according to claim 1, wherein the glass powder has a glass transition point of 400 to 490° C. and a softening point under load of 450 to 540° C.

14. The glass paste, according to claim 1, wherein a photosensitive organic ingredient is contained as the organic ingredient.

15. A process for producing a display, comprising the step of coating and drying the glass paste as set forth in claim 1 for forming a paste coating film, the step of exposing the paste coating film through a photo mask, the step of developing the exposed paste coating film, and the step of forming a pattern by firing.

16. A display obtained by the production process as set forth in claim 15.
